(19) United States
(12) Patent Application Publication
(10) Pub. No.: US 2016/0264403 A1
(43) Pub. Date: Sep. 15, 2016

(54) SENSOR DEVICE WITH MULTI-STIMULUS SENSING AND METHOD OF FABRICATION

(71) Applicant: FREESCALE SEMICONDUCTO, INC., AUSTIN, TX (US)

(72) Inventors: MAMUR CHOWDHURY, CHANDLER, AZ (US); BRUNO J. DEBEURRE, PHOENIX, AZ (US); MATTHIEU LAGOUGE, BROSSARD (CA); DAVID J. MONK, MESA, AZ (US); BABAK A. TAHERI, PHOENIX, AZ (US)

(21) Appl. No.: 14/656,336

(22) Filed: Mar. 12, 2015

(51) Int. Cl. B81B 7/02; B81C 1/00

(52) U.S. Cl. CPC B81B 7/02; B81C 1/00214

(57) ABSTRACT

A sensor device includes sensors that sense different physical stimuli. Fabrication of the device entails forming a device structure having a first and second wafer layers with a signal routing layer interposed between them. Active transducer elements of one or more sensors are formed in the second wafer layer. A third wafer layer is attached with the second wafer layer to produce one or more cavities in which the active transducer elements are located. Ports may be formed in the third wafer layer to adjust the pressure within the cavities during manufacture. The third wafer layer includes either a reference element or diaphragm of a pressure sensor. A fourth wafer layer may be coupled to the third wafer layer. The third and fourth wafer layers can include active and non-active circuitry such as integrated circuits, sensor components, microcontrollers, and the like.

### TECHNICAL FIELD OF THE INVENTION

The present invention relates generally to sensor devices. More specifically, the present invention relates to a sensor device with multiple stimulus sensing capability and a method of fabricating the sensor device.

### BACKGROUND OF THE INVENTION

Microelectromechanical systems (MEMS) devices are semiconductor devices with embedded mechanical components. MEMS devices include, for example, pressure sensors, accelerometers, gyroscopes, microphones, digital mirror displays, micro fluidic devices, resonators, flow sensors, and so forth. MEMS devices are used in a variety of products such as automobile airbag systems, control applications in automobiles, navigations, display systems, inkjet cartridges, and so forth.

As the uses for MEMS sensor devices continue to grow and diversify, increasing emphasis is being placed on the development of advanced silicon MEMS sensor devices capable of sensing different physical stimuli at enhanced sensitivities and for integrating these sensors into the same package. In addition, increasing emphasis is being placed on fabrication methodology for MEMS sensor devices that achieves multiple stimulus sensing capability without increasing manufacturing cost and complexity and without sacrificing part performance. Forming a sensor having multiple stimulus sensing capability in a miniaturized package has been sought for use in a number of applications. Indeed, these efforts are primarily driven by existing and potential high-volume applications in automotive, medical, commercial, and consumer products.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, the Figures are not necessarily drawn to scale, and:

FIG. 1 shows a sectional side view of a microelectromechanical systems (MEMS) sensor device having multiple stimulus sensing capability in accordance with an embodiment;

FIG. 2 shows a sectional side view of a MEMS sensor device having multiple stimulus sensing capability in accordance with another embodiment;

FIG. 3 shows a flowchart of a sensor device fabrication process in accordance with another embodiment;

FIG. 4 shows a side sectional view of a structure at an initial stage of fabrication in accordance with the process of FIG. 3;

FIG. 5 shows a side sectional view of the structure of FIG. 4 at a subsequent stage of fabrication;

FIG. 6 shows a side sectional view of the structure of FIG. 5 at a subsequent stage of fabrication;

FIG. 7 shows a side sectional view of the structure of FIG. 6 at a subsequent stage of fabrication;

FIG. 8 shows a side sectional view of the structure of FIG. 7 at a subsequent stage of fabrication;

FIG. 9 shows a side sectional view of the structure of FIG. 8 at a subsequent stage of fabrication;

FIG. 10 shows a side sectional view of the structure of FIG. 9 at a subsequent stage of fabrication;

FIG. 11 shows a side sectional view of the structure of FIG. 10 at a subsequent stage of fabrication;

FIG. 12 shows a side sectional view of the structure of FIG. 11 at a subsequent stage of fabrication;

FIG. 13 shows a side sectional view of the structure of FIG. 12 at a subsequent stage of fabrication;

FIG. 14 shows a side sectional view of a third wafer layer used to fabricate the sensor device of FIG. 1;

FIG. 15 shows a side sectional view of a third wafer layer used to fabricate the sensor device of FIG. 2;

FIG. 16 shows a side sectional view of the structure of FIG. 13 at a subsequent stage of fabrication;

FIG. 17 shows a side sectional view of a fourth wafer layer used to fabricate the sensor device of FIG. 1; and

FIG. 18 shows a side sectional view of a fourth wafer layer used to fabricate the sensor device of FIG. 2.

### DETAILED DESCRIPTION

In overview, an embodiment of the present invention entails a microelectromechanical systems (MEMS) device capable of sensing different physical stimuli and methodology for fabricating the sensor device. In particular, the sensor device includes laterally and vertically spaced integrated sensors, each of which may sense a different physical stimulus. In an embodiment, one sensor of the sensor device is a pressure sensor that uses a diaphragm and a pressure cavity to create a variable capacitor to detect strain (or deflection) due to applied pressure over an area. Other sensors of the sensor device may be an accelerometer, gyroscope, magnetometer, and so forth that are capable of creating a variable capacitance in response to sensed stimuli. In addition to sensors, a cavity under vacuum can hold a resonator for timing applications and/or for a resonant energy harvesting system. A MEMS device with multi-stimulus sensing capability can be implemented within an application calling for four or more degrees of freedom for automotive, medical, commercial, and industrial markets.

Fabrication methodology for the sensor device entails fabrication of a stacked configuration of at least three wafer layers with laterally and vertically spaced sensors. The laterally and vertically spaced sensors can include any suitable combination of, for example, a pressure sensor, microphone, accelerometers, angular rate sensors, and/or magnetometers. However, other sensors, MEMS devices, and integrated circuits may be incorporated as well. In an embodiment, the fabrication methodology enables the sensors to be located in separate isolated cavities that exhibit different cavity pressures for optimal operation of each of the sensors. Electrically conductive through-silicon vias may be implemented to eliminate the bond pad shelf of some MEMS sensor devices, thereby reducing MEMS sensor device dimensions and enabling chip scale packaging.

The fabrication methodology further enables a technique for stacking multiple wafers with different sensing circuitry to create four, six, seven, nine, and ten degree-of-freedom (DOF) sensor devices. The fabrication methodology further allows options for integration of a pressure sensor with a single crystal silicon (SCS) diaphragm and/or an SCS-based microphone with one or more inertial sensors, allows options for complimentary metal-oxide-semiconductor (CMOS) integrated sensors to be coupled with full MEMS device wafer, and allows options for integration of one or more CMOS wafers to additionally function as a cap. Accordingly, fabrication methodology described herein may yield a multiple stimulus sensor device with enhanced function, sensitivity, and durability, reduced dimensions, and that can be cost effectively fabricated utilizing existing manufacturing techniques.

The instant disclosure is provided to further explain in an enabling fashion the best modes, at the time of the application, of making and using various embodiments in accordance with the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued. It is further understood that the use of relational terms, if any, such as first and second, top and bottom, and the like are used solely to distinguish one from another entity or action without necessarily requiring or implying any actual such relationship or order between such entities or actions.

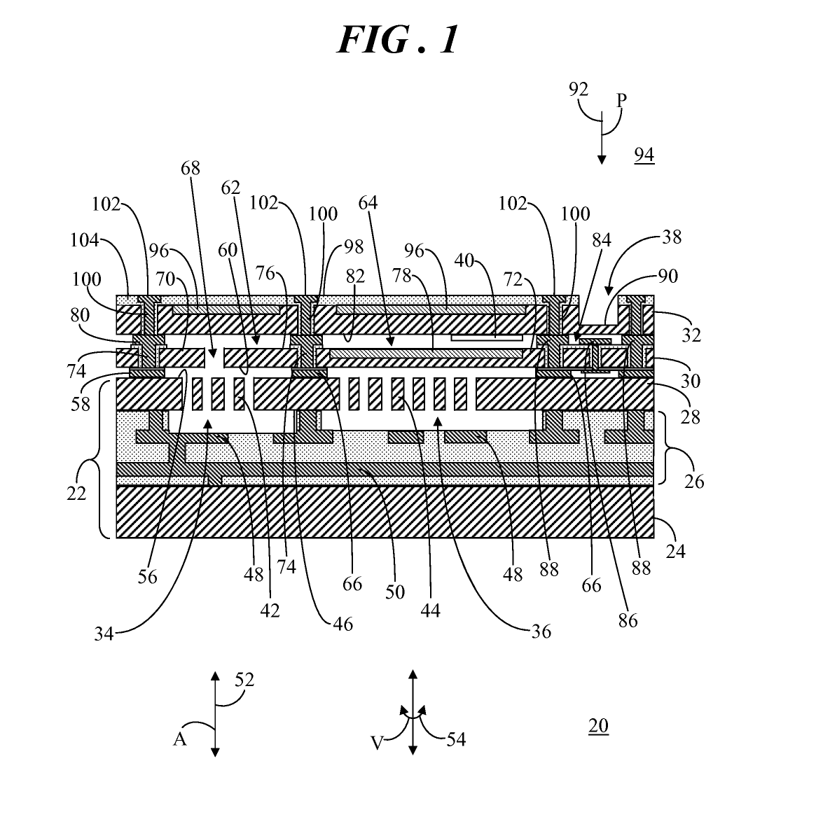

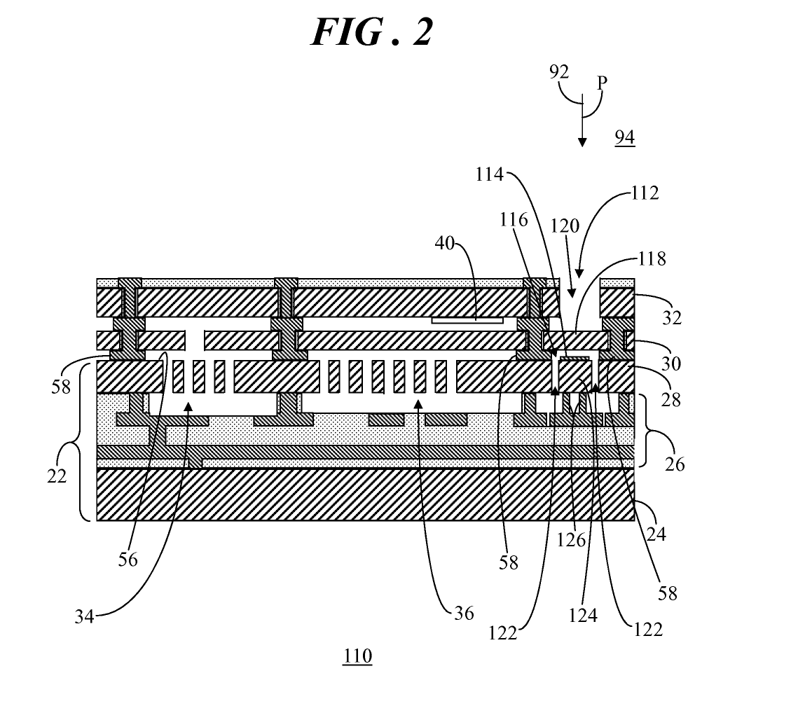

FIG. 1 shows a sectional side view of a microelectromechanical systems (MEMS) sensor device 20 having multiple stimulus sensing capability in accordance with an embodiment. FIG. 1 and subsequent FIGS. 2 and 4-18 are illustrated using various shading and/or hatching to distinguish the different elements of sensor device 20, as will be discussed below. These different elements within the structural layers may be produced utilizing current and upcoming micromachining techniques of depositing, patterning, etching, and so forth.

Sensor device 20 includes a device structure 22 having a first wafer layer 24, a signal routing layer 26 bonded to or formed on first wafer layer 24, and a second wafer layer 28. Sensor device 20 further includes a third wafer layer 30 attached with device structure 22, and a fourth wafer layer 32 coupled with third wafer layer 30. In an embodiment, sensor device 20 includes an accelerometer 34, an angular rate sensor 36, a pressure sensor 38 (or alternatively, a microphone), and a magnetometer 40. Alternative embodiments may include different sensors than those described herein.

Accelerometer 34 and angular rate sensor 36 are formed in device structure 22. More particularly, an active transducer element 42 of accelerometer 34 is formed in second wafer layer 28 of device structure 22. Active transducer element 42 may include one or more movable elements, sometimes referred to proof masses, that are capable of movement in response to an acceleration force. Similarly, an active transducer element 44 of angular rate sensor 36 is formed in second wafer layer 28 of device structure. Active transducer element 44 may include one or more movable elements that are capable of movement in response to angular velocity.

Signal routing layer 26 is coupled with, but is spaced apart from a first side 46 of second wafer layer 28. Signal routing layer 26 can include components 48 for either or both of accelerometer 34 and angular rate sensor 36 for suitably carrying output signals, for providing a ground plane 50, and the like.

In this exemplary embodiment, accelerometer 34 is configured to sense a linear acceleration stimulus (A), represented by a bi-directional arrow 52. In general, accelerometer 34 is adapted to sense linear acceleration stimulus 52 as movement of active transducer element 42 relative to fixed elements 48 underlying active transducer element 42. A change in a capacitance between the fixed elements 48 and active transducer element 42 as a function of linear acceleration stimulus 52 can be registered by sense circuitry (not shown) and converted to an output signal representative of linear acceleration stimulus 52.

Angular rate sensor 36 is configured to sense an angular rate stimulus, or velocity (V), represented by a curved bi-directional arrow 54. In general, angular rate sensor 32 is adapted to sense angular rate stimulus 54 as movement of active transducer element 44 relative to fixed elements 48 underlying active transducer element 44. A change in a capacitance between the fixed elements 48 and active transducer element 44 as a function of angular rate stimulus 54 can be registered by sense circuitry (not shown) and converted to an output signal representative of angular rate stimulus 54.

Only generalized descriptions of single axis inertial sensors, i.e., accelerometer 34 and angular rate sensor 36, are provided herein for brevity. It should be understood that in alternative embodiments, accelerometer 34 can be any of a plurality of single and multiple axis accelerometer structures configured to sense linear motion in one or more directions. Likewise, angular rate sensor 36 can be any of a plurality of single and multiple axis angular rate sensor structures configured to sense angular rate about one or more axes of rotation.

Third wafer layer 30 is attached with a second side 56 of second wafer layer 28. In some embodiments, third wafer layer 30 is coupled to second side 56 of second wafer layer 28 using an electrically conductive bonding layer 58 that forms a conductive interconnection between device structure 22 and third wafer layer 30. Conductive bonding layer 58 may be implemented using a two layer metal-based bonding technique, for example, eutectic Aluminum-Germanium (Al-Ge) bonding, eutectic Gold-Tin (Au-Sn) bonding, thermocompression Copper-Copper (Cu-Cu) bonding, Copper-Tin (Cu-Sn) bonding, Aluminum-Silicon (Al-Si) bonding, and so forth. Alternatively, third wafer layer 30 may be coupled to second side 56 of second wafer layer 28 using direct bonding, i.e., silicon-silicon and/or silicon-polysilicon.

Conductive bonding layer 58 may be suitably thick so that a bottom side 60 of third wafer layer 30 is displaced away from and does not contact second side 56 of device structure 22 thereby producing at least one hermetically sealed cavity in which accelerometer 34 and angular rate sensor 36 are located. In some configurations, spacers (not shown) may be utilized to so that bottom side 60 of third wafer layer is displaced away from second side 56 of device structure. And in still other configurations, third wafer layer 30 may additionally have cavity regions (not shown) extending inwardly from bottom side 60 of third wafer layer to enlarge (i.e., deepen) the at least one hermetically sealed cavity.

In the illustrated embodiment, device structure 22 of sensor device 20 includes at least two physically isolated and hermetically sealed cavities 62, 64. That is, conductive bonding layer 58, interconnecting third wafer layer 30 with device structure 22, is formed to include multiple sections 66 defining boundaries between the physically isolated cavities 62, 64. In the exemplary embodiment, accelerometer 34 is located in cavity 62 and angular rate sensor 36 is located in cavity 64.

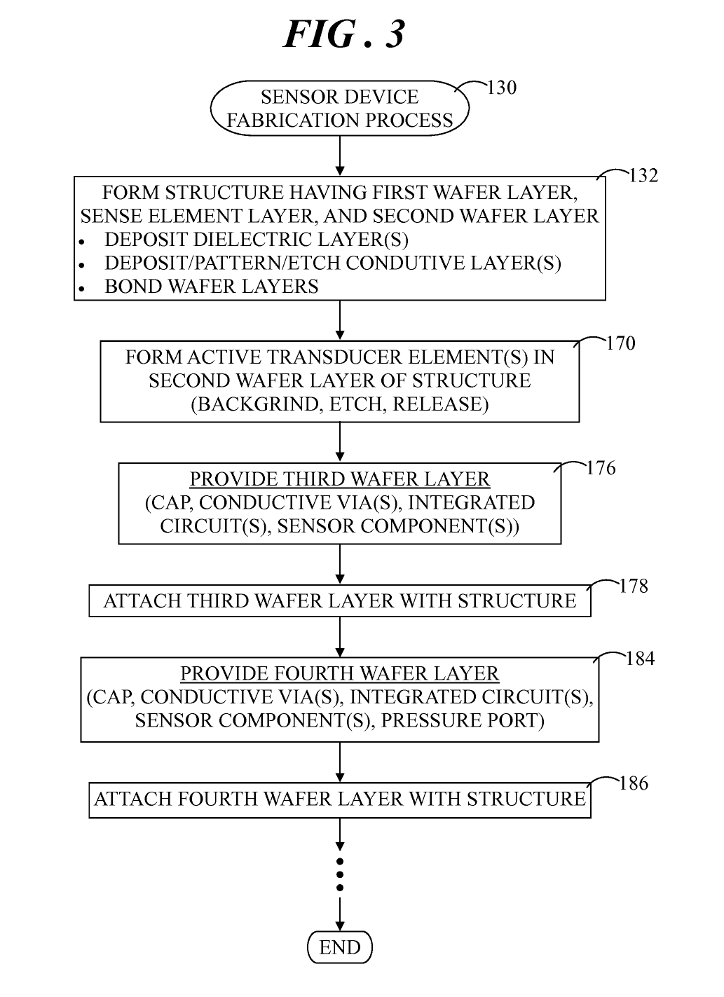

It should be noted that a port 68 extends through a first portion 70 of third wafer layer 30 that is aligned with cavity 62. However, a port does not extend through a second portion 72 of third wafer layer 30 that is aligned with cavity 64. Port 68 enables cavity 62 to be in fluid communication with an external environment at least temporarily during fabrication, as will be discussed below. However, the absence of a port through second portion of third wafer layer 30 enables cavity 64 to be effectively isolated from the external environment during certain process operations to produce cavity 64 having a different cavity pressure than a cavity pressure of cavity 62. This feature will be described in significantly greater detail in connection with fabrication methodology presented in FIG. 3.

Third wafer layer 30 may further include at least one electrically conductive through-silicon via (TSV) 74, also known as a vertical electrical connection, extending through third wafer layer 30 from bottom side 60 of third wafer layer 30 to a top side 76 of third wafer layer 30. Conductive vias 74 may be electrically coupled with conductive bonding layer 58 to suitably carry signals to and from accelerometer 34 and/or angular rate sensor 36 of device structure 22.

In the illustrated embodiment, an integrated circuit 78 may be formed in or on top side 76 of third wafer layer 30 (as shown) and/or in or on bottom side 60 of third wafer layer 30. Integrated circuit 78 represents any control circuitry, microprocessor(s), memory, sensors, and other digital logic circuits pertinent to the function of sensor device 20. Third wafer layer 30 may be suitably processed to produce integrated circuit 78 utilizing, for example, CMOS process techniques. In alternative embodiments, however, third wafer layer 30 need not include integrated circuit 78, and may instead serve as a cap structure for accelerometer 34 and angular rate sensor 36.

Fourth cap layer 32 is coupled with top side 76 of third wafer layer 30 using, for example, an electrically conductive bonding layer 80 that forms a conductive interconnection between third wafer layer 30 and fourth wafer layer 32. Again, conductive bonding layer 80 may be suitably thick so that a bottom side 82 of fourth wafer layer 32 is displaced away from and does not contact top side 76 of third wafer layer 30 thereby producing one or more hermetically sealed cavities in which other components may be located. Again, spacers (not shown) may be utilized to displace fourth wafer layer 32 away from third wafer layer 30.

As shown in FIG. 1, a port does not extend through fourth wafer layer 32. Therefore, after fourth wafer layer 32 is coupled with third wafer layer 32, port 68 is effectively sealed so that cavity 62 housing accelerometer 34 is sealed to protect the movable elements of accelerometer 34, e.g., active transducer element 42 from external contaminants.

In the illustrated embodiment, the coupling of fourth wafer layer 32 with third wafer layer 30 produces a physically isolated and hermetically sealed cavity region, referred to herein as a pressure cavity 84, between third and fourth wafer layers 30, 32 for pressure sensor 38. As such, a pressure sensor element, referred to herein as a reference element 86, may first be formed on top side 76 of third wafer layer 30. In such a configuration, bond layer 80 may serve as an anchor region 88 fully surrounding reference element 86 to thereby produce pressure cavity 84 in which reference element 86 is located. A conductive via 87 may be formed extending through third wafer layer 30. Conductive via 87 may be positioned under and in electrical communication with reference element 86. Conductive via 87 may be coupled with conductive bonding layer 58 to suitably carry signals to or from reference element 86, or to interconnect reference element 86 with ground. Fourth wafer layer 32 includes a thinned portion 90 vertically aligned with reference element 86. Thinned portion 90 functions as an active transducer element, in the form of a diaphragm for pressure sensor 38. As such, thinned portion 90 will be referred to hereinafter as diaphragm 90.

In an embodiment, pressure sensor 38 is configured to sense a pressure stimulus (P), represented by an arrow 92, from an environment 94 external to sensor device 20. Pressure sensor 38 includes reference element 86 and diaphragm 90 in a vertically aligned relationship, where diaphragm 90 is spaced apart from reference element 86 so as to form a gap between diaphragm 90 and reference element 86. Diaphragm 90 is exposed to external environment 94, and is capable of movement in a direction that is generally perpendicular to a plane of sensor device 20 in response to pressure stimulus 92 from external environment 94. Pressure sensor 38 uses diaphragm 90 and the pressure within pressure cavity 84 (typically less than atmospheric pressure) to create a variable capacitor to detect strain due to applied pressure, i.e., pressure stimulus 92. As such, pressure sensor 38 senses pressure stimulus 92 from environment 94 as movement of diaphragm 90 (i.e., the active transducer element) relative to reference element 86. A change in capacitance between reference element 86 and diaphragm 90 as a function of pressure stimulus 92 can be registered by sense circuitry (not shown) and converted to an output signal representative of pressure stimulus 92.

Like third wafer layer 30, one or more integrated circuits 96 may be formed in or on a top side 98 of fourth wafer layer 32 (as shown) and/or in or on bottom side 82 of fourth wafer layer 32. For example, magnetometer 40 is formed on bottom side 82 of fourth wafer layer 32. Magnetometer 40 may be a single axis or multiple axis magnetic field sensor fabricated in accordance with known methodologies and materials. Integrated circuits 96 represent any control circuitry, microprocessor(s), memory, sensors, and other digital logic circuits pertinent to the function of sensor device 20. Fourth wafer layer 32 may be suitably processed to produce integrated circuits 96 utilizing, for example, CMOS process techniques. In alternative embodiments, however, fourth wafer layer 32 need not include integrated circuits 96 and/or magnetometer 40, and may instead serve as a simple cap structure for accelerometer 34 and as a diaphragm 90 for pressure sensor 38.

Fourth wafer layer 32 may further include at least one electrically conductive through-silicon via (TSV) 100 extending through fourth wafer layer 32 from bottom side 82 of fourth wafer layer 32 to top side 98 of fourth wafer layer 32. Conductive vias 100 may be electrically coupled with conductive bonding layer 80 to suitably carry signals to and from accelerometer 34 and angular rate sensor 36 of device structure 22, integrated circuit 76, and so forth. Additionally, conductive vias 100 may be electrically coupled to conductive interconnects 102 embedded in a dielectric layer 104 formed on top side 98 of fourth wafer layer 32.

Conductive interconnects 102 may be located at top side 98 of fourth wafer layer 32 in lieu of their typically location laterally displaced from, i.e., beside, the device structure on a bond pad shelf. As such, in an embodiment, conductive interconnects 104 may be attached to a circuit board via a solder ball technique when sensor device 20 is packaged in a flip chip configuration. Such vertical integration effectively reduces the footprint of sensor device 20 relative to some prior art sensor devices. Only three conductive vias 100 and conductive interconnects 102 are shown for simplicity of illustration. However, it should be understood that sensor device 20 may any suitable quantity of conductive vias 100, where one each of conductive vias 100 is electrically connected to a particular conductive interconnect 102.

FIG. 2 shows a sectional side view of a MEMS sensor device 110 having multiple stimulus sensing capability in accordance with another embodiment. Sensor device 110 includes a number of features and components in common with sensor device 20 (FIG. 1). That is, sensor device 110 includes device structure 22 having first wafer layer 24, signal routing layer 26 bonded to first wafer layer 24, and second wafer layer 28. Sensor device 20 further includes third wafer layer 30 attached with device structure 22, and forth wafer layer 32 coupled with third wafer layer 30. In an embodiment, sensor device 110 includes accelerometer 34, angular rate sensor 36, and magnetometer 40. Details of these components will not be repeated herein for brevity.

In accordance with this alternative embodiment, MEMS sensor device 110 includes a pressure sensor 112. However, pressure sensor 112 varies slightly from pressure sensor 38 (FIG. 1). In particular, pressure sensor 112 includes a reference element 114 formed on second side 56 of second wafer layer 28. When third wafer layer 30 is attached to second side of second wafer layer 28, bonding layer 58 (as an anchor region) is suitably positioned to fully surround reference element 114 so as to form a cavity region 116 in which reference element 114 is located. A portion of third wafer layer 30, vertically aligned with reference element 114, functions as a diaphragm 118 for pressure sensor 112, and a port 120 vertically aligned with diaphragm 118 is formed extending through fourth wafer layer 32 so as to expose diaphragm 118 to external environment 94 and enable sensing of pressure stimulus 92.

It should be observed that second wafer layer 28 is suitably fabricated to electrically isolate reference element 114. As shown, a trench 122 is formed in second wafer layer 28 extending around reference element 114. Thus, reference element 114 is positioned on a platform region 124 of second wafer layer 28. Platform region 124 may be electrically connected to conductive structures 126 formed in signal routing layer 26 to suitably carry signals to or from reference element 114 or to interconnect reference element 114 with ground.

Various MEMS sensor device packages include a sealed cap that covers the active transducer elements and seals them from moisture and foreign materials that could have deleterious effects on device operation. Additionally, some MEMS sensor devices have particular pressure requirements in which they most effectively operate. For example, a MEMS pressure sensor is typically fabricated so that the pressure within its cavity is below atmospheric pressure, and more particularly near vacuum. Angular rate sensors may also most effectively operate in a vacuum atmosphere in order to achieve a high quality factor for low voltage operation and high signal response. Conversely, other types of MEMS sensor devices should operate in a non-vacuum environment in order to avoid an underdamped response in which movable elements of the device can undergo multiple oscillations in response to a single disturbance. By way of example, an accelerometer may require operation in a damped mode in order to reduce shock and vibration sensitivity. Therefore, multiple sensors in a single package may have different pressure requirements for the cavities in which they are located.

Accordingly, methodology described in detail below provides a technique for fabricating a space efficient, multi-stimulus MEMS sensor device, such as sensor device 20 or sensor device 110, in which multiple sensors can be integrated on a single chip, but can be located in separate isolated cavities that exhibit different cavity pressures suitable for effective operation of each of the sensors. Moreover, the multi-stimulus sensor device can be cost effectively fabricated utilizing existing manufacturing techniques.

FIG. 3 shows a flowchart of a sensor device fabrication process 130 for producing a multi-stimulus MEMS sensor device, such as MEMS sensor device 20 (FIG. 1) or MEMS sensor device 110 (FIG. 2). Process 130 generally describes methodology for concurrently forming the elements of the laterally spaced sensors 34, 36, 38. Fabrication process 130 implements known and developing MEMS micromachining technologies to cost effectively yield sensor devices 20, 110 having multiple stimulus sensing capability. Fabrication process 130 is described below in connection with the fabrication of a single sensor device. However, it should be understood by those skilled in the art that the following process allows for concurrent wafer-level manufacturing of a plurality of sensor devices. The individual sensor devices can then be separated, cut, or diced in a conventional manner to provide individual sensor devices that can be integrated into an end application.

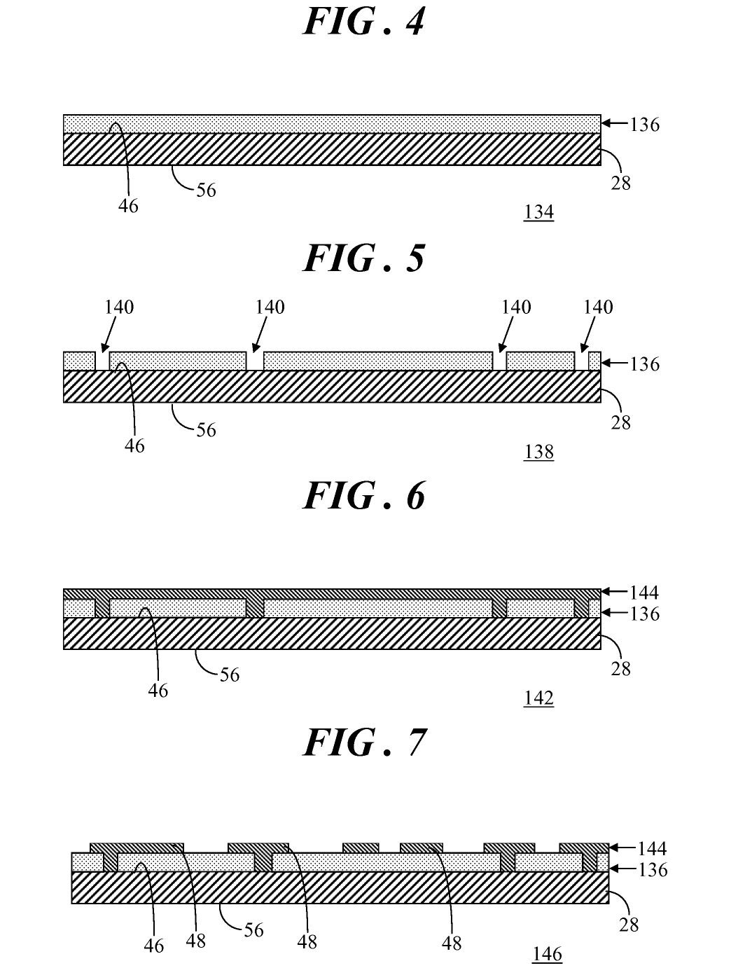

Sensor device fabrication process 130 begins with a block 132. At block 132, fabrication processes related to the formation of device structure 22 are performed. These fabrication processes entail deposition of insulating dielectric layers, deposition of electrically conductive layers, etch operations, and bonding of first and second wafer layers 24, 28 to produce device structure 22. Exemplary fabrication processes related to the formation of device structure 22 are described in connection with FIGS. 4-12.

Referring now to FIG. 4, FIG. 4 shows a side sectional view of a structure at an initial stage 134 of fabrication in accordance with fabrication process of FIG. 3. In an embodiment, device structure 22 is formed by building material layers onto second wafer layer 28, which may be a silicon wafer. At initial stage 134, an insulating dielectric layer 136 may be deposited on first side 46 of second wafer layer 28. Insulating layer 136 may be, for example, silicon oxide, phosphosilicate glass (PSG), or any other suitable electrically isolating material. Other fabrication activities may be performed per convention that are not discussed or illustrated herein for clarity of description.

FIG. 5 shows a side sectional view of the structure of FIG. 4 at a subsequent stage 138 of fabrication. At stage 138, portions of insulating layer 136 may be removed in accordance with a particular design configuration using any suitable etch process to form openings 140 extending through insulating layer 136 to first side 46 of second wafer layer 28.

FIG. 6 shows a side sectional view of the structure of FIG. 5 at a subsequent stage 142 of fabrication. At stage 142, an electrically conductive material layer 144 is formed over insulating layer 136 and in openings 140. Material layer 144 may be formed by, for example, chemical vapor deposition, physical vapor deposition, or any other suitable process. Material layer 144 may be, for example, polycrystalline silicon also referred to as polysilicon or simply poly, although other suitable electrically conductive materials may alternatively be utilized to form material layer 144.

FIG. 7 shows a side sectional view of the structure of FIG. 6 at a subsequent stage 146 of fabrication. At stage 146, material layer 144 may be selectively patterned and etched to form one or more components 48 of accelerometer 34 (FIG. 1) and/or angular rate sensor 36 (FIG. 1). These components 48 can include, for example, electrode elements, conductive traces, conductive pads, and so forth, in accordance with predetermined design requirements. Material layer 144 may additionally be thinned and polished by performing, for example, Chemical-Mechanical Planarization (CMP) or another suitable process to yield one or more components 48 of accelerometer 34 and angular rate sensor 36.

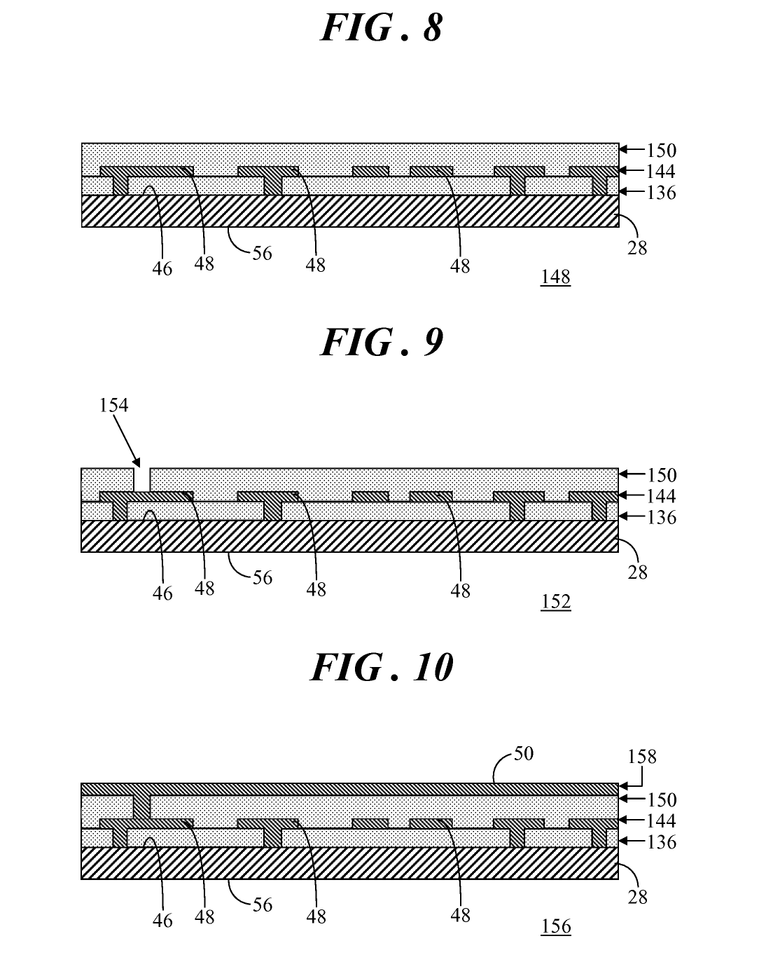

FIG. 8 shows a side sectional view of the structure of FIG. 7 at a subsequent stage 148 of fabrication. At stage 148, an insulating dielectric layer 150 may be deposited on components 48 and any exposed portions of the underlying insulating layer 136.

FIG. 9 shows a side sectional view of the structure of FIG. 8 at a subsequent stage 152 of fabrication. At stage 152, portions of insulating layer 150 may be removed in accordance with a particular design configuration using any suitable etch process to form openings 154 (one shown) extending through insulating layer 150 to at least some of components 48. Other openings (not shown) may additionally or alternatively be formed to extend to first side 46 of second wafer layer 28.

FIG. 10 shows a side sectional view of the structure of FIG. 9 at a subsequent stage 156 of fabrication. At stage 156, another electrically conductive material layer 158 is formed over insulating layer 150 and in openings 154. Material layer 158 may be formed by, for example, chemical vapor deposition, physical vapor deposition, or any other suitable process. Material layer 158 may be, for example, polycrystalline silicon also referred to as polysilicon or simply poly, although other suitable materials may alternatively be utilized to form material layer 158, where material layer 158 will eventually form ground plane 50 of device structure 22 (FIG. 1).

FIG. 11 shows a side sectional view of the structure of FIG. 10 at a subsequent stage 160 of fabrication. At stage 160, an insulating dielectric layer 162 may be deposited on material layer 158, portions of insulating layer 162 may be removed to form openings 164 (one shown) through insulating layer 162 to ground plane 50 and/or at least some of components 48, and an electrically conductive material layer 166 (such as, polysilicon) may be deposited in openings 164. Thus, at stage 160, the various material layers of signal routing layer 26 are formed. Those skilled in the art will recognize that signal routing layer 26 may have more than or less than the illustrated conductive and dielectric layers suitably formed in accordance with a particular design.

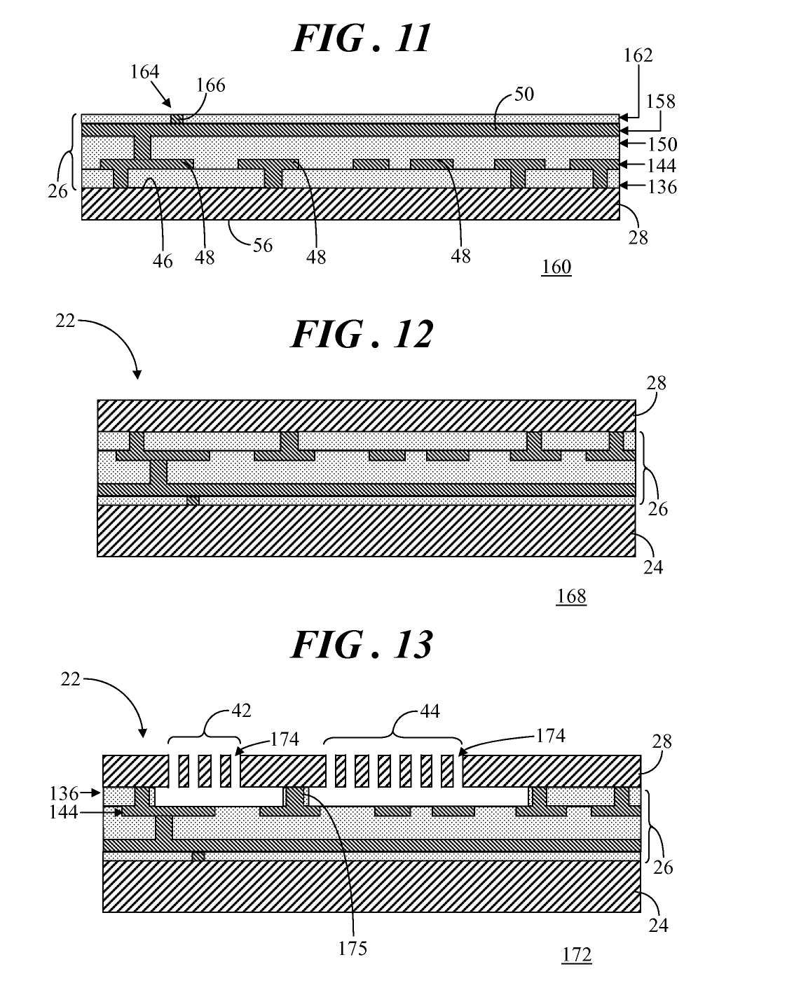

FIG. 12 shows a side sectional view of the structure of FIG. 11 at a subsequent stage 168 of fabrication. At stage 168, the structure of FIG. 11 is flipped and the exposed surface of signal routing layer 26 is bonded to first wafer layer 24 to produce device structure 22. Following bonding, second wafer layer 28 of device structure 22 may be thinned from the full wafer thickness to the desired transducer thickness. The typical thickness of the transducer elements can be from fifteen to sixty microns. Thereafter, first wafer layer 24 can function as a handle and as a ground wafer for the components of second wafer layer 28 and signal routing layer 26.

Referring back to FIG. 3, following device structure formation block 132, a block 170 is performed. At block 170, fabrication processes related to forming the active transducer elements in the second wafer layer of the device structure are performed. Exemplary fabrication processes related to the formation of the active transducer elements in the second wafer layer are described in connection with FIG. 13.

Referring now to FIG. 13, FIG. 13 shows a side sectional view of the structure of FIG. 12 at a subsequent stage 172 of fabrication. At stage 172, second wafer layer 28 is patterned and etched using, for example, a Deep Reactive Ion Etch (DRIE) technique or any suitable process to form active transducer element 42 of accelerometer 34 (FIG. 1), active transducer element 44 of angular rate sensor 36 (FIG. 1), and another other elements of sensors 34, 36 in accordance with a particular design configuration of sensor device 20 (FIG. 1) or sensor device 110 (FIG. 2).

In addition, at least a portion of insulating dielectric layer 136 underlying active transducer elements 42, 44 is removed to allow movement of, i.e., release of, active transducer elements 42, 44. By way of example, an etch material or etchant may be introduced via openings 174 or spaces between active transducer elements 42, 44 in a known manner in order to remove the underlying insulating layer 136. It should be observed that a portion 175 of insulating layer 136 and material layer 144 may remain following DRIE so that the cavities 62, 64 (FIG. 1) in which active transducer elements 42, 44 will eventually be located are physically isolated from one another.

Returning back to FIG. 3, sensor device fabrication process 130 continues with blocks 176 and 178. At block 176, the third wafer layer is provided and at block 178 the third wafer layer is attached with device structure 22 (FIG. 1).

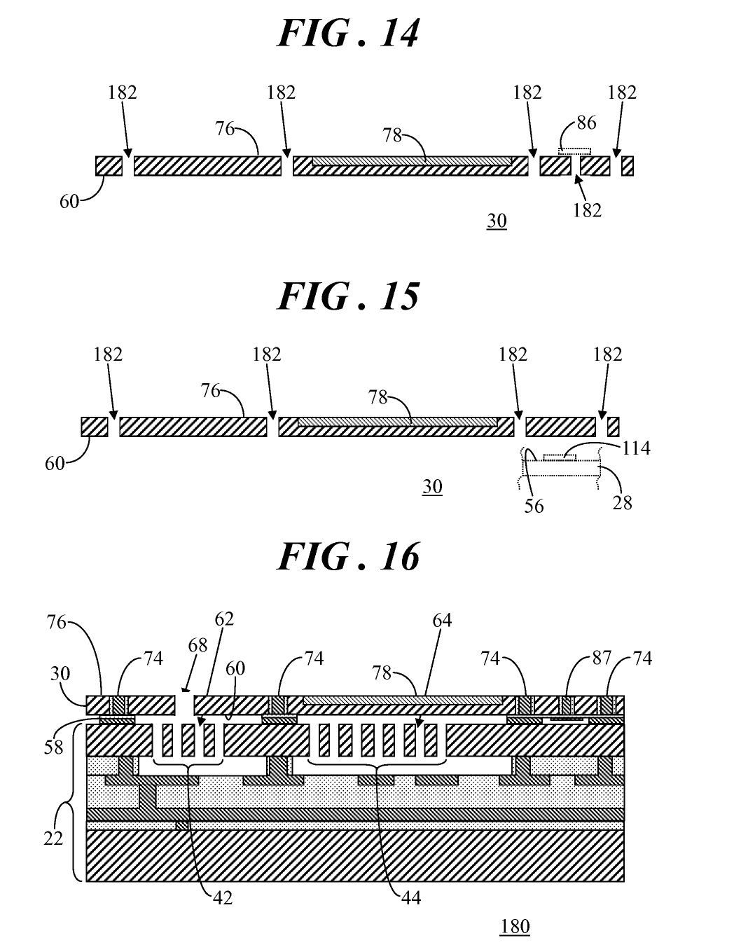

Referring to FIGS. 14-16 in connection with process blocks 176 and 178, FIG. 14 shows a side sectional view of third wafer layer 30 used to fabricate sensor device 20 (FIG. 1). FIG. 15 shows a side sectional view of third wafer layer 30 used to fabricate sensor device 110 (FIG. 2), and FIG. 16 shows a side sectional view of the structure of FIG. 13 at a subsequent stage 180 of fabrication.

As shown in both of FIGS. 14 and 15, integrated circuit 78 is formed on or in third wafer layer 30 at top side 76. In the illustrated embodiment, when integrated circuit 78 is formed on or in third wafer layer 30 at top side 76, fabrication methodology may entail bonding top side 76 of third wafer layer 30 with another wafer (not shown) using a temporary bonding technique. Thereafter, third wafer layer 30 can be thinned from bottom side 60. Following thinning, third wafer layer 30 can be attached to device structure 22. In an alternative embodiment, integrated circuit 78 may be formed on the opposite side of third wafer layer 30, i.e., on bottom side 60 (not shown). In such a configuration, bottom side 60 of third wafer layer 30 can first be attached to device structure 22. Thereafter, third wafer layer 30 can be thinned from top side 78.

Reference element 86 for pressure sensor 38 (FIG. 1) is shown in dotted line form on top side 76 of third wafer layer 30. Reference element 86 is shown in FIG. 14 prior to attaching third wafer layer 30 to device structure 22 for simplicity. In an embodiment, reference element 86 may actually be formed by deposition on top side 76 following attachment of third wafer layer 30 to device structure 22. Reference element 114 for pressure sensor 112 (FIG. 2) is shown in dotted line form proximate bottom side 60 of third wafer layer 30 in order to visualize its eventual position relative to third wafer layer 30.

Additionally, third wafer layer 30 may include pre-formed openings 182 extending through the thickness of third wafer layer 30, although preformed openings 182 are not a requirement. Openings 182 are formed at the locations at which conductive vias 74 (FIG. 1) and conductive via 87 (FIG. 1) will be formed.

At stage 180 shown in FIG. 16, third wafer layer 30 illustrated in FIG. 14 is attached to device structure 22 via bonding layer 58. In an embodiment, conductive bonding layer 58 may be produced utilizing a two layer metal bonding technique such as eutectic Al-Ge, eutectic AuSn, thermocompression Cu-Cu, or any of a variety of the bonding materials or by direct bonding, as mentioned above.

In an embodiment, attaching block 178 (FIG. 3) of fabrication process 130 represented at stage 180, may be performed under pressure conditions that are less than ambient pressure. For example, the attaching process may be performed under vacuum conditions. Thus, once bonded, cavity 64 in which active transducer element 44 for angular rate sensor 36 (FIG. 1) is located is formed with evacuated pressure. That is, the pressure within cavity 64 can be significantly less than ambient or atmospheric pressure.

After third wafer layer 30 is coupled with device structure 22, conductive vias 74 and 87 may be formed. As mentioned above, openings 182 may be pre-formed in third wafer layer 30. Alternatively, openings 182 may be formed extending through an entirety of third wafer layer 30 following attachment to device structure 22. Openings 182 may be formed using DRIE, KOH, or any suitable etch techniques. Thereafter, openings 182 may be filled with an electrically insulating material, apertures may be formed extending through the insulating material residing in openings 182, and a conductive material may be positioned in the apertures to form an electrically conductive connection (i.e., conductive vias 74 and 87s) between bottom side 60 and top side 76 of third wafer layer 30. Further details for forming conductive vias 74 are not provided for brevity.

Port 68 may be formed following attaching task 178, following thinning of third wafer layer 30, and after conductive vias 74 have been formed. As such once the structure shown in FIG. 16 is removed from a vacuum environment, cavity 62 will not remain at vacuum due to the presence of port 68. In general, conductive bonding layer 58 entirely encircles the perimeter of each cavities 62 and 64. Accordingly, conductive bonding layer 50 not only forms a seal for each of cavities 62 and 64, it additionally facilitates the conductive interconnection between the structures of device structure 22 and those on the remainder of device sensor 20.

Returning back to FIG. 3, fabrication process 130 continues with blocks 184 and 186. At block 184, the fourth wafer layer is provided and at block 186, the fourth wafer layer is coupled to the third wafer layer. Following process block 186, other processes may be performed in accordance with standard manufacturing techniques as represented by the ellipses in FIG. 3. These other processes can include, but are not limited to, wafer level testing, attachment of solder balls, wafer dicing, and so forth. Thereafter, sensor device fabrication process 130 ends.

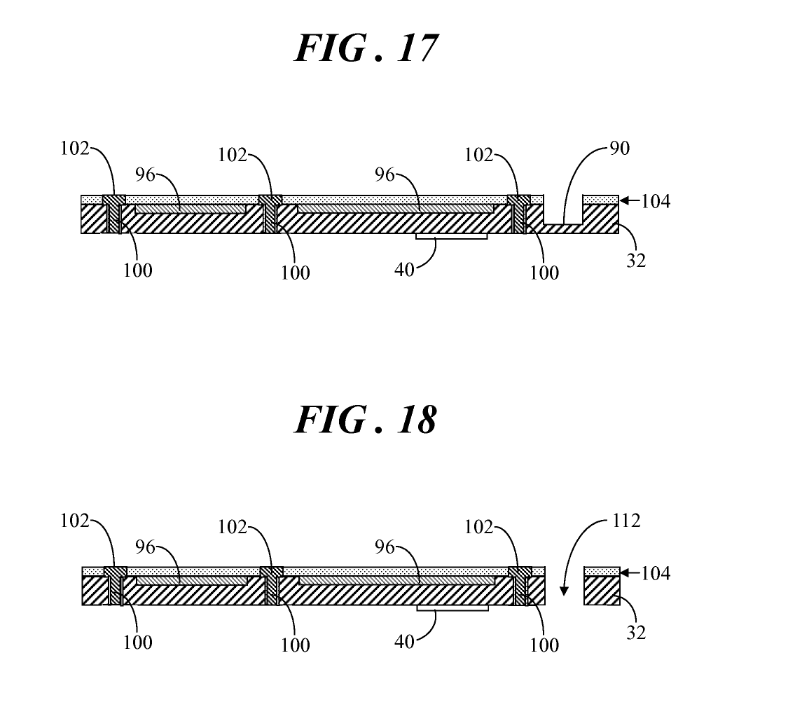

Referring to FIGS. 17 and 18 in connection with process blocks 184 and 186, FIG. 17 shows a side sectional view of fourth wafer layer 32 used to fabricate sensor device 20 (FIG. 1) and FIG. 18 shows a side sectional view of fourth wafer layer 32 used to fabricate sensor device 110 (FIG. 2). As shown in FIG. 17, fourth wafer layer 32 includes magnetometer 40, integrated circuits 96, conductive vias 100, conductive interconnects 100, dielectric layer 104, and a thinned portion that forms diaphragm 90. As shown in FIG. 18, fourth wafer layer 32 magnetometer 40, integrated circuits 96, conductive vias 100, conductive interconnects 100, dielectric layer 104, and pressure port 112. In some embodiments, fourth wafer layer 32 may be fully processed prior to its coupling with third wafer 30 (FIG. 1), as shown in FIGS. 17 and 18. In other embodiments, fourth wafer layer 32 may be partially fabricated prior to its coupling with third wafer layer 30, such that the remaining process operations are performed after fourth wafer layer 32 is coupled with third wafer layer 30.

It is to be understood that certain ones of the process blocks depicted in FIG. 3 may be performed in parallel with each other or with performing other processes. In addition, it is to be understood that the particular ordering of the process blocks depicted in FIG. 3 may be modified, while achieving substantially the same result. Accordingly, such modifications are intended to be included within the scope of the inventive subject matter. Further, the phraseology or terminology employed herein is for the purpose of description and not of limitation.

Thus, a microelectromechanical systems (MEMS) sensor device capable of sensing different physical stimuli and methodology for fabricating the sensor device have been described. An embodiment of a method of producing a sensor device comprises forming a device structure having a first wafer layer, a signal routing layer bonded to the first wafer layer, and a second wafer layer having a first side coupled with and spaced apart from the signal routing layer. The method further comprises forming a first active transducer element of a first sensor in the second wafer layer and attaching a third wafer layer with a second side of the second wafer layer. The attaching operation produces a cavity in which the first active transducer element is located, the third wafer layer including one of a second sense element and a second active transducer element of a second sensor laterally spaced apart from the first sensor.

An embodiment of a sensor device comprises a device structure having a first wafer layer, a signal routing layer bonded to the first wafer layer, and a second wafer layer having a first side coupled with and spaced apart from the signal routing layer, wherein a first active transducer element of a first sensor is formed in the second wafer layer. The sensor device further comprises a third wafer layer attached with a second side of the second wafer layer to produce a cavity in which the first active transducer element is located, the third wafer layer including one of a second sense element and a second active transducer element of a second sensor laterally spaced apart from the first sensor.

The processes and devices, discussed above, and the inventive principles thereof are enables a technique for stacking multiple wafers with different sensing circuitry to create four, six, seven, nine, and ten degree-of-freedom (DOF) sensor devices. The fabrication methodology further allows options for integration of a pressure sensor with a single crystal silicon (SCS) diaphragm and/or an SCS-based microphone with one or more inertial sensors, allows options for complimentary metal-oxide-semiconductor (CMOS) integrated sensors to be coupled with full MEMS device wafer, and allows options for integration of one or more CMOS wafers to additionally function as a cap.

The sensor device produced using the fabrication methodology therefore can include laterally and vertically spaced integrated sensors, each of which may sense a different physical stimulus, and each housed in separate isolated cavities that exhibit different cavity pressures for optimal operation of each of the sensors. One sensor of the sensor device is a pressure sensor that uses a diaphragm and a pressure cavity to create a variable capacitor to detect strain (or deflection) due to applied pressure over an area. Other sensors of the sensor device may be an accelerometer, gyroscope, magnetometer, and so forth that are capable of creating a variable capacitance in response to sensed stimuli. A sensor device with multi-stimulus sensing capability can be implemented within an application calling for four or more degrees of freedom for automotive, medical, commercial, and industrial markets. Accordingly, fabrication methodology described herein may yield a multiple stimulus sensor device with enhanced function, sensitivity, and durability, reduced dimensions, and that can be cost effectively fabricated utilizing existing manufacturing techniques.

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

What is claimed is:

1. A method of producing a sensor device comprising:
forming a device structure having a first wafer layer, a signal routing layer bonded to said first wafer layer, and a second wafer layer having a first side coupled with said signal routing layer;
forming a first active transducer element of a first sensor in said second wafer layer; and
attaching a third wafer layer with a second side of said second wafer layer, said attaching operation producing a cavity in which said first active transducer element is located, said third wafer layer including one of a second sense element and a second active transducer element of a second sensor laterally spaced apart from said first sensor.

2. The method of claim 1 further comprising forming a third active transducer element of a third sensor in said second wafer layer, said third active transducer element being laterally spaced apart from each of said first and second sensors.

3. The method of claim 2 wherein said cavity is a first cavity, said attaching said third wafer layer produces a second cavity, said second cavity being physically isolated from said first cavity, and said third active transducer being located in said second cavity.

4. The method of claim 3 further comprising producing said first cavity to have a first cavity pressure that is different from a second cavity pressure of said second cavity.

5. The method of claim 3 wherein:
said method further comprises forming a port extending through a first portion of said third wafer layer and no port extending through a second portion of said third wafer layer; and
said attaching comprises bonding said third wafer layer with said second side of said second wafer layer such that said first cavity is in fluid communication with an external environment via said port and said second cavity is isolated from said external environment.

6. The method of claim 5 further comprising following said bonding operation, sealing said port such that said first cavity is isolated from said external environment.

7. The method of claim 1 when said third wafer layer includes said second sense element, said method further comprises:
coupling a fourth wafer layer with said third wafer layer such that said second sense element is located in a cavity region between said third and fourth wafer layers;
thinning a portion of said fourth wafer layer vertically aligned with said second sense element to form a diaphragm of said second sensor, said diaphragm being movable in response to a pressure stimulus from an external environment.

8. The method of claim 7 further comprising fabricating said fourth wafer layer to include at least one of an integrated circuit and a fourth sensor.

9. The method of claim 1 wherein when said third wafer layer includes said second active transducer element, said method further comprises forming said second sense element on said second side of said second wafer layer prior to said attaching operation, and wherein:
said attaching operation forms a cavity region between said second and third wafer layers in which said second sense element is located;
said second active transducer element in said third wafer layer is a diaphragm of said second sensor; and
said diaphragm is movable in response to a pressure stimulus from an external environment.

10. The method of claim 9 wherein said attaching comprises forming an anchor region extending between said second and third wafer layers, said anchor surrounding a periphery of said diaphragm.

11. The method of claim 9 further comprising:
providing a fourth wafer layer having a pressure port extending through said fourth wafer layer; and
coupling said fourth wafer layer with said third wafer layer such that said pressure port is aligned with said diaphragm.

12. The method of claim 1 further comprising prior to said attaching operation, fabricating said third wafer layer to include at least one of an integrated circuit and a fourth sensor.

13. A method of producing a sensor device comprising:
forming a device structure having a first wafer layer, a signal routing layer bonded to said first wafer layer, and a second wafer layer having a first side coupled with and spaced apart from said signal routing layer;
forming a first active transducer element of a first sensor in said second wafer layer;
forming a second active transducer element of a second sensor in said second wafer layer, said second active transducer element being laterally space apart from said first sensor; and
attaching a third wafer layer with a second side of said second wafer layer, said attaching operation producing a first cavity in which said first active transducer element is located and a second cavity in which said second active transducer element is located, said second cavity being physically isolated from said first cavity, and said third wafer layer including one of a third sense element and a third active transducer element of a third sensor laterally spaced apart from said first and second sensors.

14. The method of claim 13 wherein:
said method further comprises forming a port extending through a first portion of said third wafer layer and no port extending through a second portion of said third wafer layer; and
said attaching comprises bonding said third wafer layer with said second side of said second wafer layer such that said first cavity is in fluid communication with an external environment via said port and said second cavity is isolated from said external environment to produce said first cavity having a first cavity pressure that is different from a second cavity pressure of said second cavity.

15. The method of claim 14 further comprising following said bonding operation, sealing said port such that said first cavity is isolated from said external environment.

16. The method of claim 13 wherein when said third wafer layer includes said third sense element, said method further comprises:
coupling a fourth wafer layer with said third wafer layer such that said third sense element is located in a cavity region between said third and fourth wafer layers;
thinning a portion of said fourth wafer layer vertically aligned with said third sense element to form a diaphragm of said third sensor, said diaphragm being movable in response to a pressure stimulus from an external environment.

17. The method of claim 13 wherein when said third wafer layer includes said third active transducer element, said method further comprises forming said third sense element on said second side of said second wafer layer prior to said attaching operation, and wherein:
said attaching operation forms a cavity region between said second and third wafer layers in which said third sense element is located;
said third active transducer element in said third wafer layer is a diaphragm of said third sensor; and
said diaphragm is movable in response to a pressure stimulus from an external environment.

18. A sensor device comprising:
a device structure having a first wafer layer, a signal routing layer bonded to said first wafer layer, and a second wafer layer having a first side coupled with and spaced apart from said signal routing layer;
a first active transducer element of a first sensor is formed in said second wafer layer; and
a third wafer layer attached with a second side of said second wafer layer to produce a cavity in which said first active transducer element is located, said third wafer layer including one of a second sense element and a second active transducer element of a second sensor laterally spaced apart from said first sensor.

19. A sensor device as claimed in claim 18 wherein:
when said third wafer layer includes said second sense element, said sensor device further comprises a fourth wafer layer coupled with said third wafer layer such that said second sense element is located in a cavity region between said third and fourth wafer layers; and
said fourth wafer layer includes a thinned portion vertically aligned with said second sense element to form a diaphragm of said second sensor, said diaphragm being movable in response to a pressure stimulus from an external environment.

20. A sensor device as claimed in claim 18 wherein:
said second sense element is formed on said second side of said second wafer layer and is located in a cavity region between said second and third wafer layers; and
said third wafer layer includes said second active transducer element, said second active transducer element being a diaphragm of said pressure sensor, wherein said diaphragm is movable in response to a pressure stimulus from an external environment.
